(19) United States
(12) Patent Application Publication
(10) Pub. No.: US 2021/0370789 A1
(43) Pub. Date: Dec. 2, 2021

(54) BATTERY STATE DETERMINATION DEVICE, METHOD, AND NON-TRANSITORY STORAGE MEDIUM

(71) Applicant: TOYOTA JIDOSHA KABUSHIKI KAISHA, Toyota-shi (JP)

(72) Inventors: Toshihiro KAWAI, Okazaki-shi (JP); Shinichi INOUE, Okazaki-shi (JP); Yasushi KUSAKA, Toyota-shi (JP); Toru ONO, Toyota-shi (JP)

(73) Assignee: TOYOTA JIDOSHA KABUSHIKI KAISHA, Toyota-shi (JP)

(21) Appl. No.: 17/327,043

(22) Filed: May 21, 2021

(30) Foreign Application Priority Data
Jun. 1, 2020 (JP) 2020-095581

(51) Int. Cl. B60L 53/62; H02J 7/00; G01R 31/68

(52) U.S. Cl. CPC B60L 53/62; G01R 31/68; H02J 7/0047

(57) ABSTRACT

A battery state determination device that determines a state of a connection terminal of a battery includes: a current detection unit configured to detect a value of current flowing into or a value of current flowing out of the battery, and a determination unit configured to determine that the connection terminal of the battery is disconnected based on the current value detected by the current detection unit during charging of the battery without using voltage values of the battery.

### CROSS-REFERENCE TO RELATED APPLICATION

This application claims priority to Japanese Patent Application No. 2020-095581 filed on Jun. 1, 2020, incorporated herein by reference in its entirety.

### BACKGROUND

### 1. Technical Field

The present disclosure relates to a battery state determination device, method and non-transitory storage medium used in a vehicle equipped with a battery.

### 2. Description of Related Art

Japanese Unexamined Patent Application Publication No. 2017-046502 (JP 2017-046502 A) proposes a device for determining disconnection of a connection terminal of a battery. The device determines whether the battery connection terminal is disconnected based on whether a first condition that input and output current of the battery is within a predetermined range (current threshold) and a second condition that a terminal voltage of the battery is within a predetermined range (voltage threshold) are both satisfied.

### SUMMARY

However, a voltage of the battery detected by a voltage detector, etc. includes errors and fluctuations. Therefore, it is difficult to set the voltage threshold with which disconnection of the connection terminal of the battery is accurately determined through comparison with the detected voltage value. Therefore, further improvement of determination on whether the connection terminal of the battery is desired.

The disclosure provides a battery state determination device, method and non-transitory storage medium of which accuracy for determining whether the connection terminal of the battery is disconnected is improved.

A first aspect of the present disclosure relates to a battery state determination device that determines a state of a connection terminal of a battery. The battery state determination device includes: a current detection unit configured to detect a value of current flowing into the battery or a value of current flowing out of the battery; and a determination unit configured to determine that the connection terminal of the battery is disconnected based on the current value detected by the current detection unit during charging of the battery without using voltage values of the battery.

In the first aspect, the determination unit may be configured to determine that the connection terminal of the battery is disconnected when a state in which a fluctuation range of the current value detected by the current detection unit is less than a first threshold continues for a first time, or the determination unit may be configured to determine that the connection terminal of the battery is disconnected when a state in which the current value detected by the current detection unit is less than a second threshold continues for a second time during the charging of the battery.

In the first aspect, the determination unit may be configured to determine that the connection terminal of the battery is disconnected when a decrease equal to or more than predetermined threshold occurs with the current value detected by the current detection unit within a predetermined period during charging of the battery. Further, the determination unit may be configured to determine that the connection terminal of the battery is disconnected when the decrease equal to or more than the predetermined threshold occurs with the current value detected by the current detection unit within the predetermined period after a predetermined time or more has elapsed from start of charging the battery.

A second aspect of the present disclosure relates to a state determination method for a connection terminal of a battery. The method includes: detecting a value of current flowing into the battery or a value of current flowing out of the battery; and determining that the connection terminal of the battery is disconnected based on the detected current value during charging of the battery without using voltage values of the battery.

A third aspect of the present disclosure relates to a non-transitory storage medium storing instructions that are executable by one or more processors and that cause the one or more processors to perform functions for determining a state of a connection terminal of a battery. The function includes: detecting a value of current flowing into the battery or a value of current flowing out of the battery; and determining that the connection terminal of the battery is disconnected based on the detected current value during charging of the battery without using voltage values of the battery.

With the battery state determination device, etc. according to the present disclosure, disconnection of the connection terminal of the battery is determined without using the voltage value with which errors and fluctuations are likely to occur. Therefore, accurate determination can be made.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram showing a schematic configuration of a battery state determination device according to an embodiment;

FIG. 2 is a flowchart showing a processing procedure of a first control for a terminal disconnection determination;

FIG. 3 is a flowchart showing a processing procedure of a second control for the terminal disconnection determination; and

FIG. 4 is a flowchart showing a processing procedure of a third control for the terminal disconnection determination.

### DETAILED DESCRIPTION OF EMBODIMENTS

A battery state determination device according to the present disclosure determines whether a connection terminal of a battery is disconnected based on current flowing into or current flowing out of the battery that is detected by a current detection unit. Accurate determination can be made because disconnection of the connection terminal of the battery is determined without using voltage values with which errors and fluctuations are likely to occur. Hereinafter, embodiments of the present disclosure will be described in detail with reference to the drawings.

### Embodiment

Configuration

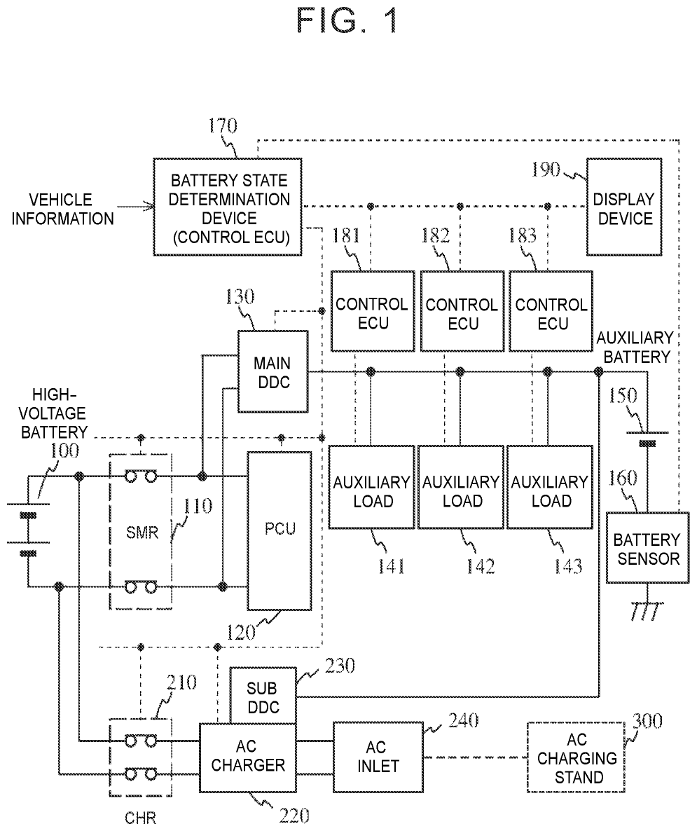

FIG. 1 is a functional block diagram of a battery state determination device 170 and its peripheral portions according to an embodiment of the present disclosure. FIG. 1 illustrates a functional block of a plug-in electric vehicle equipped with the battery state determination device 170. The functional block illustrated in FIG. 1 mainly includes a high-voltage battery 100, a power control unit (PCU) 120, a main direct current-direct current (DC-DC) converter (main DDC) 130, and a plurality of auxiliary loads 141, 142, 143, an auxiliary battery 150, a battery sensor 160, the battery state determination device 170, a plurality of control ECUs 181, 182, 183, and an alternate current (AC) charger 220. In FIG. 1, signal lines for electric power are represented by solid lines, and signal lines for control and communication are shown by broken lines.

The high-voltage battery 100 is a high-voltage secondary battery such as a lithium-ion battery that can be charged and discharged, and is a drive battery used for supplying the electric power to a so-called main engine mounted on a vehicle, for example. The high-voltage battery 100 is connected to the power control unit (PCU) 120 and the main DC-DC converter (main DDC) 130 via a system main relay (SMR) 110, and can supply the electric power to the power control unit (PCU) 120 and the main DC-DC converter 130. The power control unit 120 is a device for controlling a predetermined device required for driving a vehicle, such as a motor generator (not shown). Further, the high-voltage battery 100 can receive the electric power from the AC charger 220 via a charge relay (CHR) 210.

The AC charger 220 is connected to an AC charging stand 300. The AC charging stand 300 is an external power supply facility via an AC inlet 240. The AC charger 220 can supply the electric power to the high-voltage battery 100 and the main DC-DC converter (main DDC) 130 under a control of a sub DC-DC converter (sub DDC) 230.

The main DC-DC converter (main DDC) 130 can output the electric power stored in the high-voltage battery 100 and the electric power supplied from the AC charger 220 to the auxiliary loads 141, 142, 143, and the auxiliary battery 150 at a predetermined voltage. The main DC-DC converter 130 is controlled by the battery state determination device 170 that is a control electronic control unit (ECU).

The auxiliary loads 141, 142, 143 are so-called auxiliary devices mounted on the vehicle, and are loads that consume the electric power required to perform a predetermined operation. The auxiliary loads 141, 142, 143 can be classified into, for example, a load that consumes large current in a short term, a load that consumes large current in a long term, and a load that consumes small current. FIG. 1 shows an example in which three auxiliary loads are mounted on the vehicle. However, two or less or four or more auxiliary loads may be mounted on the vehicle. Operations of the auxiliary loads 141, 142, 143, etc. are controlled by control ECUs 181, 182, 183 that are provided for the auxiliary loads 141, 142, 143, respectively.

The auxiliary battery 150 is a secondary battery that is configured to be chargeable and dischargeable, such as a lead-acid battery and a lithium-ion battery, and a low-voltage battery used for supplying the electric power to auxiliary devices mounted on the vehicle, for example. The auxiliary battery 150 can store the electric power output from the high-voltage battery 100 and the AC charger 220. A battery state of the auxiliary battery 150 is monitored by the battery sensor 160. The battery sensor 160 according to the present embodiment includes a current sensor that functions as a current detection unit, and detects current flowing into the auxiliary battery 150 and current flowing out of the auxiliary battery 150. The current value detected by the battery sensor 160 is output to the battery state determination device 170 as needed.

The battery state determination device 170 is connected to the system main relay (SMR) 110, the power control unit (PCU) 120, the main DC-DC converter (main DDC) 130, the control ECUs 181, 182, 183, a display device 190, and the charge relay (CHR) 210, and the AC charger 220 in a controllable manner. The battery state determination device 170 according to the present embodiment determines whether the connection terminal of the auxiliary battery 150 is disconnected based on operational states of the auxiliary battery 150 and the main DC-DC converter 130 acquired from the battery sensor 160. Further, the battery state determination device 170 controls the operational state of the main DC-DC converter 130 based on vehicle information indicating a vehicle condition. Examples of the vehicle information include a state of a courtesy switch, a state of a door lock, and a state of a start-stop push switch.

The battery state determination device 170 may typically include a part or all of an electronic control device (ECU) including a processor, a memory, an input and output interface, etc. The electronic control device includes an ECU that can control connection and disconnection states of the system main relay (SMR) 110 and the charge relay (CHR) 210, an ECU that can control the output voltage value of the main DC-DC converter (main DDC) 130, an ECU that can monitor the state of the auxiliary battery 150, and an ECU that can control an operational state of the AC charger 220. The battery state determination device 170 realizes a function of determining whether the connection terminal of the auxiliary battery 150 is disconnected by causing the processor to read a program stored in the memory and execute the program.

When the vehicle equipped with the battery state determination device 170 is an electric vehicle that does not adopt a plug-in charging system, the AC charger 220 and other components related to external charging are omitted from the configuration shown in FIG. 1. Further, when the vehicle equipped with the battery state determination device 170 is not an electric vehicle using a motor and a vehicle using an internal combustion engine, the configuration shown in FIG. 1 may include a power generator such as an alternator to supply the electric power to the main DC-DC converter (main DDC) 130.

Control

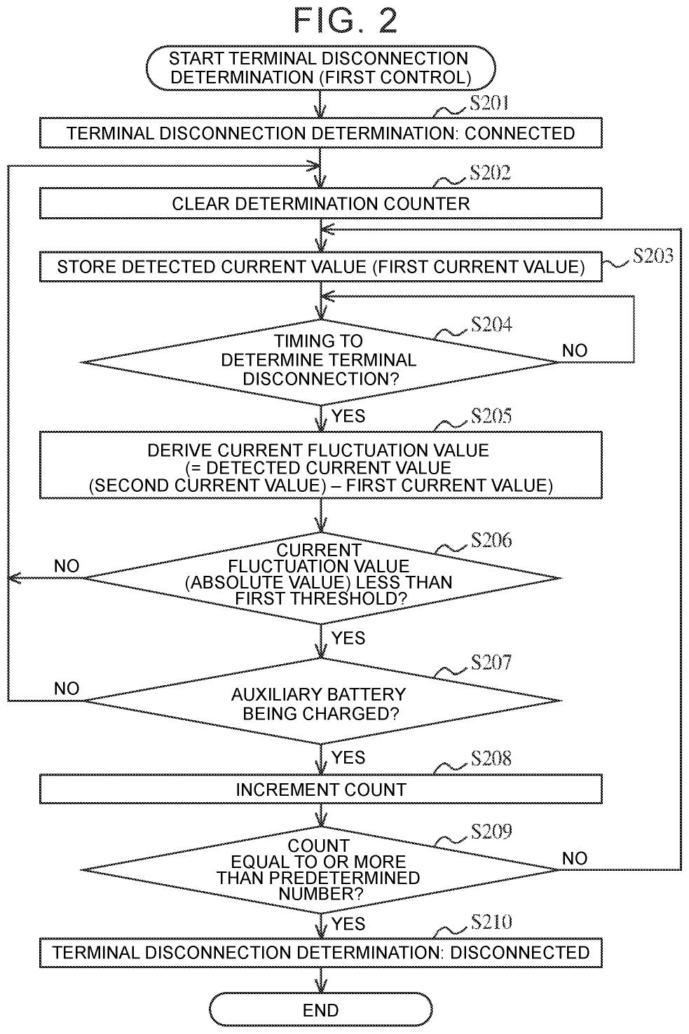

The control executed by the battery state determination device 170 according to the embodiment of the present disclosure will be described with reference to FIGS. 2 to 4. FIGS. 2 to 4 are flowcharts of terminal disconnection determination control for determining whether the connection terminal of the auxiliary battery 150 is disconnected, which is executed by the battery state determination device 170.

(1) First Control for Terminal Disconnection Determination

FIG. 2 is a flowchart showing a processing procedure of a first control for a terminal disconnection determination executed by the battery state determination device 170. The first control shown in FIG. 2 is repeatedly executed while the battery state determination device 170 is in operation.

Step S201

The battery state determination device 170 sets a state of the connection terminal of the auxiliary battery 150 to a state in which the terminal is connected (connected state), and initializes a determination result. The initialization of the determination result above can be performed, for example, by turning off a predetermined flag (terminal disconnection determination flag) indicating whether the connection terminal is disconnected. When the battery state determination device 170 sets the state of the connection terminal to the connected state, the processing proceeds to step S202.

Step S202

The battery state determination device 170 clears a predetermined determination counter and resets a count value to zero. The determination counter is used to measure time during which (or the number of times that) the state in which the connection terminal of the auxiliary battery 150 is disconnected continues. When the determination counter is cleared, the processing proceeds to step S203.

Step S203

The battery state determination device 170 acquires, from the battery sensor 160, a value of current flowing into the auxiliary battery 150 or a value of current flowing out from the auxiliary battery 150 that is detected by the battery sensor 160 at present (detected current value). The battery state determination device 170 stores the acquired detected current value as a signed first current value in a storage unit (not shown), etc. For example, the value of the current flowing into the auxiliary battery 150 is affixed with a positive sign, and the value of the current flowing out of the auxiliary battery 150 is affixed with a negative sign. When the first current value is stored, the processing proceeds to step S204.

Step S204

The battery state determination device 170 determines whether it is a timing to determine whether the connection terminal of the auxiliary battery 150 is disconnected. For example, when the terminal disconnection determination is repeatedly executed in a predetermined cycle, the timing can be set to the timing at which time corresponding to the cycle has elapsed from the time when the terminal disconnection determination is executed last time. Further, the terminal disconnection determination may be executed at the timing when a predetermined event occurs. When it is the timing to execute the terminal disconnection determination (YES in step S204), the processing proceeds to step S205. In other cases (NO in step S204), the processing waits until the timing to execute the terminal disconnection determination is reached.

Step S205

The battery state determination device 170 derives a current fluctuation value indicating a degree of fluctuation of the current flowing through the auxiliary battery 150. The current fluctuation value can be obtained by subtracting the first current value (past value) stored in step S203 from a second current value (present value) that is the present value of the current flowing into or out of the auxiliary battery 150 (detected current value) acquired from the battery sensor 160. When the current fluctuation value is derived, the processing proceeds to step S206.

Step S206

The battery state determination device 170 determines whether an absolute value of the derived current fluctuation value is less than a first threshold. With the processing above, whether a change equal to or more than the first threshold occurs with the current value of the auxiliary battery 150 can be determined. The first threshold can be determined based on a resolution when the detected value of the battery sensor 160 is converted through an analog-digital conversion. For example, one quantization step (approximately 0.03 amperes) of the battery sensor 160 obtained based on one quantization step (approximately 0.3 volt) of an AD converter having a reference voltage being 5 volts and the resolution being 4 bits (16 steps) can be set to the first threshold. When the absolute value of the current fluctuation value is less than the first threshold (YES in step S206), the processing proceeds to step S207. When the absolute value of the current fluctuation value is equal to or more than the first threshold (NO in step S206). The processing returns to step S202.

Step S207

The battery state determination device 170 issues a command on the voltage to the main DC-DC converter (main DDC) 130, supplies the electric power from the high-voltage battery 100 to the auxiliary battery 150, and determines whether the auxiliary battery 150 is being charged. Alternatively, the battery state determination device 170 issues a command on the voltage to the main DC-DC converter 130 and the sub DC-DC converter (sub DDC) 230, supplies the electric power from the AC charging stand 300 to the auxiliary battery 150 via the AC charger 220, and determines whether the auxiliary battery 150 is being charged. The determination above is made to confirm whether the current of the auxiliary battery 150 is not fluctuating even though the auxiliary battery 150 is being charged. When the auxiliary battery 150 is being charged (YES in step S207), the processing proceeds to step S208. When the auxiliary battery 150 is not being charged (NO in step S207), the processing returns to step S202.

Step S208

The battery state determination device 170 increments a count of the determination counter by one. When the count is incremented, the processing proceeds to step S209.

Step S209

The battery state determination device 170 determines whether the count of the determination counter is equal to or more than a predetermined number. The determination above is made to confirm whether a state in which the current of the auxiliary battery 150 is not fluctuating even though the auxiliary battery 150 is being charged continues for a first time (=predetermined cycle×predetermined number). That is, the battery state determination device 170 determines whether a state in which the current fluctuation value (absolute value) is less than the first threshold while the auxiliary battery 150 is being charged continues for the first time by executing the processing in steps S204, S206, S207, and S209. When the count is equal to or more than a predetermined number (YES in step S209), the processing proceeds to step S210. When the count is less than the predetermined number (NO in step S209), the processing returns to step S203.

Step S210

The battery state determination device 170 determines that the connection terminal of the auxiliary battery 150 is disconnected. The determination above can be executed, for example, by turning on the predetermined terminal disconnection determination flag. When the battery state determination device 170 determines that the connection terminal is disconnected, the first control for the terminal disconnection determination ends.

(2) Second Control for Terminal Disconnection Determination

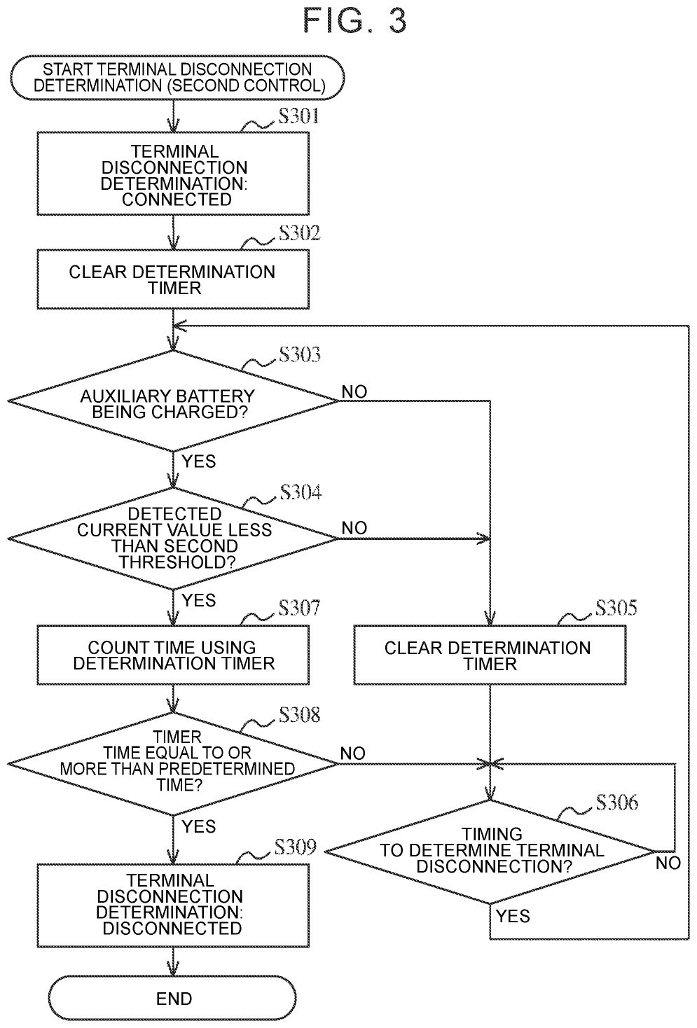

FIG. 3 is a flowchart showing a processing procedure of a second control for the terminal disconnection determination executed by the battery state determination device 170. The second control shown in FIG. 3 is repeatedly executed while the battery state determination device 170 is in operation.

Step S301

The battery state determination device 170 sets a state of the connection terminal of the auxiliary battery 150 to a state in which the terminal is connected (connected state), and initializes a determination result. The initialization of the determination result above can be performed, for example, by turning off a predetermined flag (terminal disconnection determination flag) indicating whether the connection terminal is disconnected. When the battery state determination device 170 sets the state of the connection terminal to the connected state, the processing proceeds to step S302.

Step S302

The battery state determination device 170 clears a predetermined determination timer and resets a timer time to zero. The determination timer is used to measure time during which the state in which the connection terminal of the auxiliary battery 150 is disconnected continues. When the determination timer is cleared, the processing proceeds to step S303.

Step S303

The battery state determination device 170 issues a command on the voltage to the main DC-DC converter (main DDC) 130, supplies the electric power from the high-voltage battery 100 to the auxiliary battery 150, and determines whether the auxiliary battery 150 is being charged. Alternatively, the battery state determination device 170 issues a command on the voltage to the main DC-DC converter 130 and the sub DC-DC converter (sub DDC) 230, supplies the electric power from the AC charging stand 300 to the auxiliary battery 150 via the AC charger 220, and determines whether the auxiliary battery 150 is being charged. The determination above is executed to confirm whether the current of the auxiliary battery 150 is not less than a predetermined value even though the auxiliary battery 150 is being charged. When the auxiliary battery 150 is being charged (YES in step S303), the processing proceeds to step S304. When the auxiliary battery 150 is not being charged (NO in step S303), the processing returns to step S305.

Step S304

The battery state determination device 170 acquires, from the battery sensor 160, the value of current flowing into the auxiliary battery 150 or the value of current flowing out from the auxiliary battery 150 that is detected by the battery sensor 160 at present (detected current value). The battery state determination device 170 determines whether the acquired detected current value is less than a second threshold. The determination above is executed to confirm that the current flows to the auxiliary battery 150 even though the auxiliary battery 150 is being charged. When the detected current value is less than the second threshold (YES in step S304), the processing proceeds to step S307. When the absolute value of the detected current value is equal to or more than the second threshold (NO in step S304), the processing proceeds to step S305.

Step S305

The battery state determination device 170 clears a predetermined determination timer and resets a timer time to zero. When the determination timer is cleared, the processing proceeds to step S306.

Step S306

The battery state determination device 170 determines whether it is a timing to determine whether the connection terminal of the auxiliary battery 150 is disconnected. For example, when the terminal disconnection determination is repeatedly executed in a predetermined cycle, the timing can be set to the timing at which time corresponding to the cycle has elapsed from the time when the terminal disconnection determination is executed last time. Further, the terminal disconnection determination may be executed at the timing when a predetermined event occurs. When it is the timing to execute the terminal disconnection determination (YES in step S306), the processing returns to step S303. In other cases (NO in step S306), the processing stands by until the timing to execute the terminal disconnection determination is reached.

Step S307

The battery state determination device 170 executes time counting using the determination timer. When the determination timer is cleared, the time counting is newly started. When the time is already being counted, the time counting is continued. When the time is counted using the determination timer, the processing proceeds to step S308.

Step S308

The battery state determination device 170 determines whether the timer time of the determination timer is equal to or longer than a predetermined time. The determination above is executed to confirm whether a state in which the current of the auxiliary battery 150 is small continues for a second time (=predetermined cycle×predetermined time) even though the auxiliary battery 150 is being charged. That is, the battery state determination device 170 determines whether a state in which the detected current value is less than the second threshold (e.g. 0.1 ampere) while the auxiliary battery 150 is being charged continues for the second time (e.g. 1 second) or more by executing the processing in steps S303, S304, S306, and S308 above. When the timer time is equal to or more than the predetermined time (YES in step S308), the processing proceeds to step S309. When the timer time is less than the predetermined time (NO in step S308), the processing proceeds to step S306.

Step S309

The battery state determination device 170 determines that the connection terminal of the auxiliary battery 150 is disconnected. The determination above can be executed, for example, by turning on the predetermined terminal disconnection determination flag. When the battery state determination device 170 determines that the connection terminal is disconnected, the second control for the terminal disconnection determination ends.

(3) Third Control for Terminal Disconnection Determination

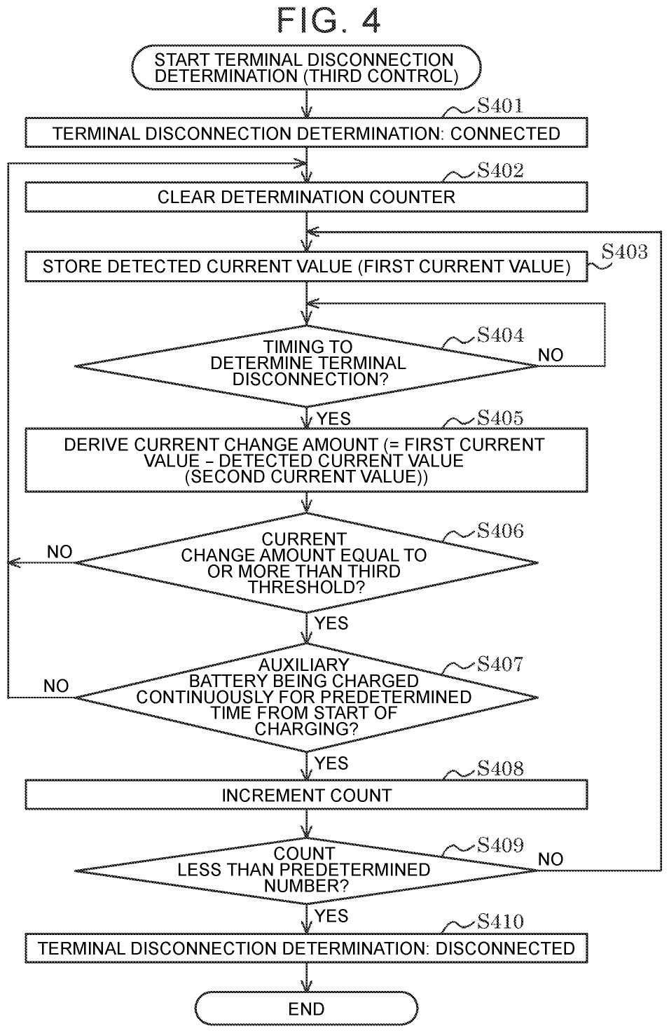

FIG. 4 is a flowchart showing a processing procedure of a third control for the terminal disconnection determination executed by the battery state determination device 170. The third control shown in FIG. 4 is repeatedly executed while the battery state determination device 170 is in operation.

Step S401

The battery state determination device 170 sets a state of the connection terminal of the auxiliary battery 150 to a state in which the terminal is connected (connected state), and initializes a determination result. The initialization of the determination result above can be performed, for example, by turning off a predetermined flag (terminal disconnection determination flag) indicating whether the connection terminal is disconnected. When the battery state determination device 170 sets the state of the connection terminal to the connected state, the processing proceeds to step S402.

Step S402

The battery state determination device 170 clears a predetermined determination counter and resets a count value to zero. The determination counter is used to measure time during which (or the number of times that) the state in which the connection terminal of the auxiliary battery 150 is disconnected continues. When the determination counter is cleared, the processing proceeds to step S403.

Step S403

The battery state determination device 170 acquires, from the battery sensor 160, the value of current flowing into the auxiliary battery 150 or the value of current flowing out from the auxiliary battery 150 that is by the battery sensor 160 at present (detected current value). The battery state determination device 170 stores the acquired detected current value as a signed first current value in a storage unit (not shown), etc. For example, a value of charging current flowing into the auxiliary battery 150 is affixed with a positive sign, and a value of discharging current flowing out of the auxiliary battery 150 is affixed with a negative sign. When the first current value is stored, the processing proceeds to step S404.

Step S404

The battery state determination device 170 determines whether it is a timing to determine whether the connection terminal of the auxiliary battery 150 is disconnected. For example, when the terminal disconnection determination is repeatedly executed in a predetermined cycle, the timing can be set to the timing at which time corresponding to the cycle has elapsed from the time when the terminal disconnection determination is executed last time. Further, the terminal disconnection determination may be executed at the timing when a predetermined event occurs. When it is the timing to execute the terminal disconnection determination (YES in step S404), the processing proceeds to step S405. In other cases (NO in step S404), the processing waits until the timing to execute the terminal disconnection determination is reached.

Step S405

The battery state determination device 170 derives a current change amount indicating a change in the value of current flowing into the auxiliary battery 150 for charging. The current change amount (charging current value) can be obtained by subtracting the second current value (present value) from the first current value (past value) stored in step S403 above. The second current value is a present value (detected current value) of current flowing into the auxiliary battery 150 or current flowing out from the auxiliary battery 150 that is acquired from the battery sensor 160. When the current change amount (charging current value) is derived, the processing proceeds to step S406.

Step S406

The battery state determination device 170 determines whether the derived current change amount (charging current value) is equal to or more than a third threshold. With the processing above, whether a decreasing change equal to or more than the third threshold occurs with the charging current value in the auxiliary battery 150 can be determined. When the current change amount (charging current value) is equal to or more than the third threshold (YES in step S406), the processing proceeds to step S407. When the current change amount (charging current value) is less than the third threshold (NO in step S406), the processing returns to step S402.

Step S407

The battery state determination device 170 issues a command on the voltage to the main DC-DC converter (main DDC) 130, and determines whether the auxiliary battery 150 is being charged continuously for a predetermined time (third time) after the high-voltage battery 100 starts supply of the electric power to the auxiliary battery 150. Alternatively, the battery state determination device 170 issues a command on the voltage to the main DC-DC converter 130 and the sub DC-DC converter (sub DDC) 230, and determines whether the auxiliary battery 150 is being charged continuously for the predetermine time after the AC charging stand 300 starts supply of the electric power to the auxiliary battery 150 via the AC charger 220. When the auxiliary battery 150 is being charged continuously for the predetermined time from the start (YES in step S407) of the supply of the electric power, the processing proceeds to step S408. When the auxiliary battery 150 is not being charged continuously for the predetermined time from the start (NO in step S407), the processing returns to step S402.

Step S408

The battery state determination device 170 increments the count of the determination counter by one. When the count is incremented, the processing proceeds to step S409.

Step S409

The battery state determination device 170 determines whether the count of the determination counter is less than a predetermined number. The determination above is executed to confirm whether the charging current to the auxiliary battery 150 is significantly decreased during the third time (=predetermined cycle×predetermined number) even when the auxiliary battery 150 is being charged. That is, the battery state determination device 170 determines whether a state in which a decrease in the charging current value is equal to or more than the third threshold (e.g. 20 amperes) within the third time (e.g. 8 milliseconds) after a predetermined time (e.g. 1 second) or more has elapsed from the start of charging by executing the processing in steps S404, S406, S407, and S409. When the count is equal to or more than a predetermined number (YES in step S409), the processing proceeds to step S410. When the count is less than the predetermined number (NO in step S409), the processing returns to step S403.

Step S410

The battery state determination device 170 determines that the connection terminal of the auxiliary battery 150 is disconnected. The determination above can be executed, for example, by turning on the predetermined terminal disconnection determination flag. When the battery state determination device 170 determines that the connection terminal is disconnected, the third control for the terminal disconnection determination ends.

The first control, the second control, and the third control for the terminal disconnection determination described above may be executed in combination of any two controls or all of the controls. Combining the plurality of controls makes it possible to improve the accuracy of determining disconnection of the connection terminal of the auxiliary battery 150.

Operations and Effects

As described above, with the battery state determination device 170 according to the embodiment of the present disclosure, whether the connection terminal of the auxiliary battery 150 is disconnected is determined based on the current flowing into or flowing out of the auxiliary battery 150 that is detected by the battery sensor 160. Specifically, when a state in which the state in which the fluctuation range of the current detected by the battery sensor 160 during charging of the auxiliary battery 150 is less than the first threshold continues for the first time, when the state in which the current detected by the battery sensor 160 during charging of the auxiliary battery 150 is less than the second threshold continues for the second time, or when a decrease equal to or more than the third threshold occurs with the current detected by the battery sensor 160 within the fourth time after the third time has elapsed from the start of charging the auxiliary battery 150, the battery state determination device 170 determines that the connection terminal of the auxiliary battery 150 is disconnected.

With the configuration above, disconnection of the connection terminal of the auxiliary battery 150 is determined without using voltage values of the auxiliary battery 150 with which errors and fluctuations are likely to occur. Therefore, accurate determination can be made.

Further, with the battery state determination device 170 according to the present embodiment, the determination processing of disconnection of the connection terminal is executed during charging of the auxiliary battery 150. Therefore, an increase in dark current can be suppressed. Further, the battery state determination device 170 according to the present embodiment is configured as the control ECU that identifies the control state of the entire vehicle (particularly the charging state of the auxiliary battery 150). Therefore, the determination processing of disconnection of the connection terminal can be effectively and accurately executed, such as avoiding execution of processing when the battery is not being charged.

Although one embodiment of the present disclosure has been described above, the present disclosure can be perceived as a battery state determination device, a state determination method executed by the battery state determination device, a state determination control program, a computer-readable non-transitory recording medium that stores the program, or a vehicle equipped with the battery state determination device.

The battery state determination device, etc. according to the present disclosure can be used for a vehicle equipped with a battery, for example.

What is claimed is:

1. A battery state determination device that determines a state of a connection terminal of a battery, the device comprising:
a current detection unit configured to detect a value of current
flowing into the battery or a value of current flowing out of the battery; and
a determination unit configured to determine that the connection terminal of the battery is disconnected based on the current value detected by the current detection unit during charging of the battery without using voltage values of the battery.

2. The battery state determination device according to claim 1, wherein the determination unit is configured to determine that the connection terminal of the battery is disconnected when a state in which a fluctuation range of the current value detected by the current detection unit is less than a first threshold continues for a first time.

3. The battery state determination device according to claim 1, wherein the determination unit is configured to determine that the connection terminal of the battery is disconnected when a state in which the current value detected by the current detection unit is less than a second threshold continues for a second time during the charging of the battery.

4. The battery state determination device according to claim 1, wherein the determination unit is configured to determine that the connection terminal of the battery is disconnected when a decrease equal to or more than predetermined threshold occurs with the current value detected by the current detection unit within a predetermined period during charging of the battery.

5. The battery state determination device according to claim 4, wherein the determination unit is configured to determine that the connection terminal of the battery is disconnected when the decrease equal to or more than the predetermined threshold occurs with the current value detected by current detection unit within the predetermined period after a predetermined time or more has elapsed from start of charging the battery.

6. A state determination method for a connection terminal of a battery, the method comprising:
detecting a value of current flowing into the battery or a value of current flowing out of the battery; and
determining that the connection terminal of the battery is disconnected based on the detected current value during charging of the battery without using voltage values of the battery.

7. A non-transitory storage medium storing instructions that are executable by one or more processors and that cause the one or more processors to perform functions for determining a state of a connection terminal of a battery, the function comprising:
detecting a value of current flowing into the battery or a value of current flowing out of the battery; and
determining that the connection terminal of the battery is disconnected based on the detected current value during charging of the battery without using voltage values of the battery.
